(19) United States
(12) Patent Application Publication
(10) Pub. No.: US 2020/0248310 A1
(43) Pub. Date: Aug. 6, 2020

(54) JOINT BLOCK AND MANUFACTURING METHOD THEREOF

(71) Applicant: FUJIKIN INCORPORATED, Osaka (JP)

(72) Inventors: Kenji AIKAWA, Osaka (JP); Kazunari WATANABE, Osaka (JP); Toshiyuki INADA, Osaka (JP); Tsutomu SHINOHARA, Osaka (JP)

(73) Assignee: FUJIKIN INCORPORATED, Osaka (JP)

(21) Appl. No.: 16/635,042

(22) PCT Filed: Aug. 17, 2018
(86) PCT No.: PCT/JP2018/030501

§ 371 Date: Jan. 29, 2020

(30) Foreign Application Priority Data
Aug. 31, 2017 (JP) 2017-166621

(51) Int. Cl. C23C 16/455; F16K 27/00; F16L 55/11; F16J 13/06

(52) U.S. Cl. CPC C23C 16/45561; C23C 16/45544; F16J 13/06; F16L 55/11; F16K 27/00

(57) ABSTRACT

A joint block includes a block body, a closing member mounted in a recessed part formed on the other end side of the block body, a seal mechanism that includes a circular projection formed on an opposing surface of the block body, and seals an area between the block body and the closing member by the circular projection biting into the other opposing surface around an opening of a first flow path, a swaging part that is formed on the block body and presses the closing member toward the opposing surface, and an engaging part formed by an inner peripheral part of the recessed part and an outer peripheral part of the closing member that engages with the inner peripheral part. A pressing force that presses the circular projection of the seal mechanism against the other opposing surface is shared by the swaging part and the engaging part.

### FIELD OF THE INVENTION

The present invention relates to a valve device and a fluid control system in which fluid devices including this valve device are integrated.

### DESCRIPTION OF THE BACKGROUND ART

In various manufacturing processes such as a semiconductor manufacturing process, a fluid control system called an integrated gas system in which various fluid devices, such as a switch valve, a regulator, and a mass flow controller, are integrated and housed in a box is used to supply an accurately measured process gas to a process chamber. This box with the integrated gas system housed therein is called a gas box.

In such an integrated gas system as described above, integration is achieved by arranging, in place of a pipe joint, a joint block that forms a flow path in a longitudinal direction of a base plate, and installing various fluid devices on this joint block (refer to Patent Documents 1 and 2, for example).

### PATENT DOCUMENTS

Patent Document 1: Japanese Laid-Open Patent Application No. H10-227368

### Patent Document 2: Japanese Laid-Open Patent Application No. 2008-298177

### Patent Document 3: Japanese Laid-Open Patent Application No. 2015-151927

### SUMMARY OF THE INVENTION

### Problems to be Solved by the Invention

To control the supply of a process gas of various manufacturing processes, higher responsiveness is required. To this end, the fluid control system needs to be miniaturized and integrated to the extent possible to install the system closer to the process chamber that is the supply destination of the fluid.

Along with the increase in size of materials to be processed, such as the increase in size of the diameter of the semiconductor wafer, it becomes necessary to also increase a supply flow rate of the fluid supplied from the fluid control system into the process chamber.

To advance miniaturization and integration of the fluid control system, it is necessary to not only advance the miniaturization of the fluid devices, but also reduce the dimensions of a joint block on which the miniaturized fluid devices are installed.

In addition, formation of a flow path that opens at two locations in the joint block is difficult. In the related art, for example, a flow path extending in a longitudinal direction of the joint block is formed by machining a hole closed on one end side and opened on the other end side in the longitudinal direction of the joint block, and fixing a closing member to an opening of this hole by welding to close the opening.

However, this method results in problems such as a flow path surface being burned by the welding, and welding residue remaining in the flow path. When the joint block is miniaturized, difficulties arise in polishing and cleaning the flow path after machining.

Patent Document 3 discloses a closing technique in which a closing member is provided at an opening of a flow path end and fixed by swaging without the use of welding. In this method, however, when dimensions of the joint block are reduced, a relatively large force is applied to the swaging part, resulting in the possibility that the joint block itself is deformed.

An object of the present invention is to provide a joint block that can be manufactured while achieving a miniaturization without the use of welding.

Another object of the present invention is to provide a manufacturing method of a joint block for manufacturing a miniaturized joint block without the use of welding.

Yet another object of the present invention is to provide a fluid control system that includes the joint block described above and is miniaturized and integrated.

### Means for Solving the Problems

A joint block of the present invention is a joint block provided with a first opening, a second opening, and a flow path connecting the first opening and the second opening, and comprises:

a block body that defines a first flow path extending in a longitudinal direction and closed on one end side and opened on the other end side in the longitudinal direction, a second flow path connected with the first flow path on one end side in the longitudinal direction and communicating with the first opening, and a third flow path connected with the first flow path on the other end side in the longitudinal direction and communicating with the second opening;

a closing member mounted in a recessed part formed on the other end side of the block body in the longitudinal direction;

a seal mechanism that includes an annular projection formed on one of opposing surfaces of the block body and the closing member opposing one another, and seals an area between the block body and the closing member by the annular projection biting into the other opposing surfaces around an opening of the first flow path;

a swaging part that is formed on the block body and presses the closing member toward the opposing surface of the block body; and

an engaging part formed by an inner peripheral part of the recessed part and an outer peripheral part of the closing member that engages with the inner peripheral part.

A pressing force that presses the annular projection of the seal mechanism against the other opposing surface is shared by the swaging part and the engaging part.

A manufacturing method of a joint block of the present invention is a manufacturing method of a joint block including a first opening, a second opening, and a flow path connecting the first opening and the second opening, and comprises the steps of:

preparing a block body that defines a first flow path extending in a longitudinal direction and closed on one end side and opened on the other end side in the longitudinal direction, a second flow path connected with the first flow path on one end side in the longitudinal direction and communicating with the first opening, and a third flow path connected with the first flow path on the other end side in the longitudinal direction and communicating with the second opening, and a closing member;

positioning the closing member in a recessed part formed on the other end side of the block body in the longitudinal direction;

press-fitting the closing member into the recessed part to form an engaging part in which an inner peripheral part of the recessed part engages with an outer peripheral part of the closing member;

deforming a swaging part formed on the block body to press the closing member toward an opposing surface of the block body; and

causing an annular projection formed on one of opposing surfaces of the block body and the closing member opposing one another to bite into the other opposing surfaces around an opening of the first flow path to seal an area therebetween.

A fluid control system of the present invention comprises a flow path between fluid devices connected using the joint block having the above-described configuration.

A semiconductor manufacturing method of the present invention comprises a step of using the fluid control system having the above-described configuration to control a process gas in a manufacturing process of a semiconductor device that requires a treatment process by the process gas in a sealed chamber.

A semiconductor manufacturing system of the present invention comprises the fluid control system having the above-described configuration to control a process gas in a manufacturing process of a semiconductor device that requires a treatment process by the process gas in a sealed chamber.

### Effect of the Invention

According to the present invention, since a force required for a seal mechanism is shared by a swaging part and an engaging part to achieve stress dispersion, it is possible to manufacture a miniaturized joint block without the use of welding while preventing deformation of a block body caused by excessive mechanical force.

### BRIEF DESCRIPTION OF THE DRAWINGS

FIG. 1 is a perspective view illustrating an example of a fluid control system in which the present invention is applied.

FIG. 2A is a top view of a joint block according to a first embodiment of the present invention.

FIG. 2B is a sectional view of the joint block in FIG. 2A in a longitudinal direction.

FIG. 2C is a side view of a closing member side of the joint block in FIG. 2A.

FIG. 3 is a main part enlarged sectional view of a block body of the joint block in FIG. 2A.

FIG. 4 is a front view of the closing member of the joint block in FIG. 2A.

FIG. 5A is a side view including a partial cross section for explaining an assembly process of the joint block according to the first embodiment of the present invention.

FIG. 5B is a side view illustrating an assembly process, continuing from FIG. 5A.

FIG. 5C is a side view illustrating an assembly process, continuing from FIG. 5B.

FIG. 5D is a side view illustrating an assembly process, continuing from FIG. 5C.

FIG. 5E is a side view including a partial cross section illustrating a state after assembly process completion of the joint block according to the first embodiment of the present invention.

FIG. 6A is a main part enlarged sectional view illustrating a modification of a protruding piece of the block body.

FIG. 6B is a main part enlarged sectional view illustrating a modification of the protruding piece of the block body.

FIG. 6C is a main part enlarged sectional view illustrating a modification of the protruding piece of the block body.

FIG. 7A is a front view of the block body of the joint block according to a second embodiment of the present invention.

FIG. 7B is a main part enlarged sectional view of the block body of the joint block according to the second embodiment of the present invention.

FIG. 8A is a side view including a partial cross section for explaining an assembly process of the joint block that uses the block body in FIG. 7A.

FIG. 8B is a side view illustrating an assembly process, continuing from FIG. 8A.

FIG. 8C is a side view illustrating an assembly process, continuing from FIG. 8B.

FIG. 8D is a side view illustrating an assembly process, continuing from FIG. 8C.

FIG. 9A is a side view including a partial cross section for explaining another assembly process of the joint block that uses the block body in FIG. 7A.

FIG. 9B is a side view illustrating an assembly process, continuing from FIG. 9A.

FIG. 10 is a main part enlarged sectional view illustrating a modification of the block body according to the second embodiment of the present invention.

FIG. 11A is a side view illustrating a modification of the block body according to the second embodiment of the present invention.

FIG. 11B is a side view including a partial cross section of the joint block that uses the block body in FIG. 11A.

FIG. 12A is a front view of a closing member according to a third embodiment of the present invention.

FIG. 12B is a main part enlarged sectional view of the block body according to the third embodiment of the present invention.

FIG. 12C is a main part enlarged sectional view of the joint block according to the third embodiment of the present invention.

FIG. 13A is a front view of the closing member of the joint block according to a fourth embodiment of the present invention.

FIG. 13B is a main part enlarged sectional view of the block body of the joint block according to the fourth embodiment of the present invention.

FIG. 13C is a side view including a partial cross section for explaining an assembly process of the joint block according to the fourth embodiment of the present invention.

FIG. 13D is a side view illustrating an assembly process, continuing from FIG. 13C.

FIG. 14A is a front view of the closing member of the joint block according to a fifth embodiment of the present invention.

FIG. 14B is a side view of the closing member in FIG. 14A.

FIG. 14C is a main part enlarged sectional view of the block body of the joint block according to the fifth embodiment of the present invention.

FIG. 14D is a front view for explaining the joint block according to the fifth embodiment of the present invention.

FIG. 14E is a front view illustrating an assembly process, continuing from FIG. 14D.

FIG. 14F is a main part sectional view illustrating an assembly process, continuing from FIG. 14E.

FIG. 15A is a front view of the closing member according to a sixth embodiment of the present invention.

FIG. 15B is a main part enlarged sectional view for explaining an assembly process of the joint block that uses the closing member according to the sixth embodiment of the present invention.

FIG. 15C is a main part enlarged sectional view illustrating an assembly process, continuing from FIG. 15B.

FIG. 16A is a front view illustrating a modification of the closing member of the joint block of the present invention.

FIG. 16B is a side view of the closing member in FIG. 16A.

FIG. 17 is a front view illustrating another modification of the closing member of the joint block of the present invention.

FIG. 18 is a front view illustrating yet another modification of the closing member of the joint block of the present invention.

FIG. 19 is a schematic diagram illustrating an application example of a fluid system according to an embodiment of the present invention to a semiconductor manufacturing process.

### DESCRIPTION OF THE PREFERRED EMBODIMENTS

Embodiments of the present invention are described below with reference to the drawings.

### First Embodiment

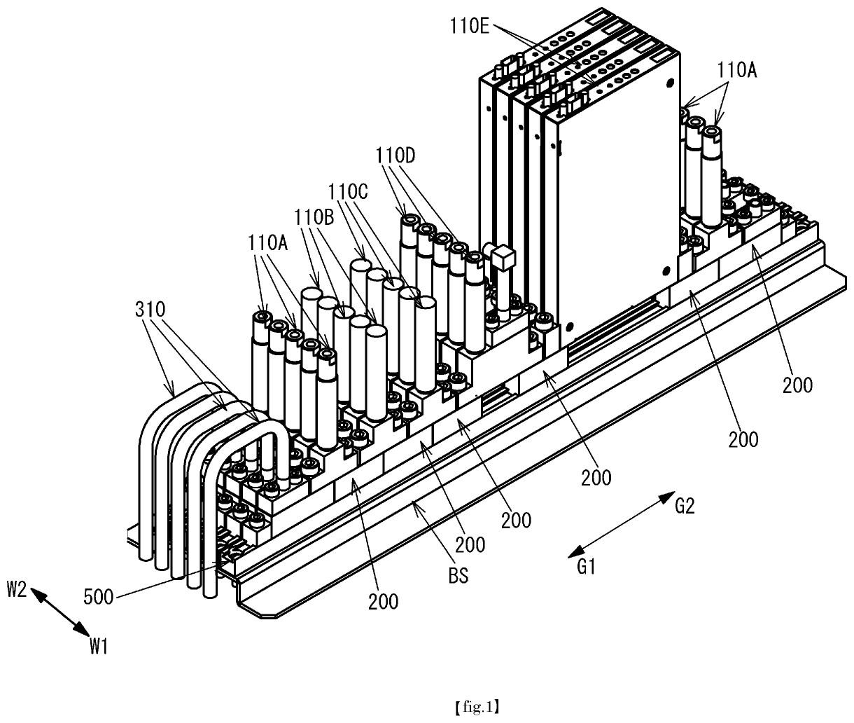

First, an example of a fluid control system in which the present invention is applied will be described with reference to FIG. 1.

The fluid control system illustrated in FIG. 1 is provided with five rail members 500 arranged in width directions W1, W2 and extending in longitudinal directions G1, G2 on a base plate BS made of metal. It should be noted that W1, W2, G1, and G2 denote front side, back side, upstream side, and downstream side directions, respectively. In each rail member 500, various fluid devices 110A to 110E are installed via a plurality of joint blocks 200, and flow paths (not illustrated) through which a fluid flows from the upstream side toward the downstream side are formed by the plurality of joint blocks 200.

Here, “fluid device” is a device used in a fluid control system for controlling a flow of a fluid, and includes a body defining a flow path, and at least two flow path ports that open at a surface of this body. Specifically, the fluid device includes a switch valve (two-way valve) 110A, a regulator 110B, a pressure gauge 110C, a switch valve (three-way valve) 110D, a mass flow controller 110E, and the like, but is not necessarily limited thereto. It should be noted that an introducing pipe 310 is connected to each of the flow path ports on the upstream side of the flow path (not illustrated) described above.

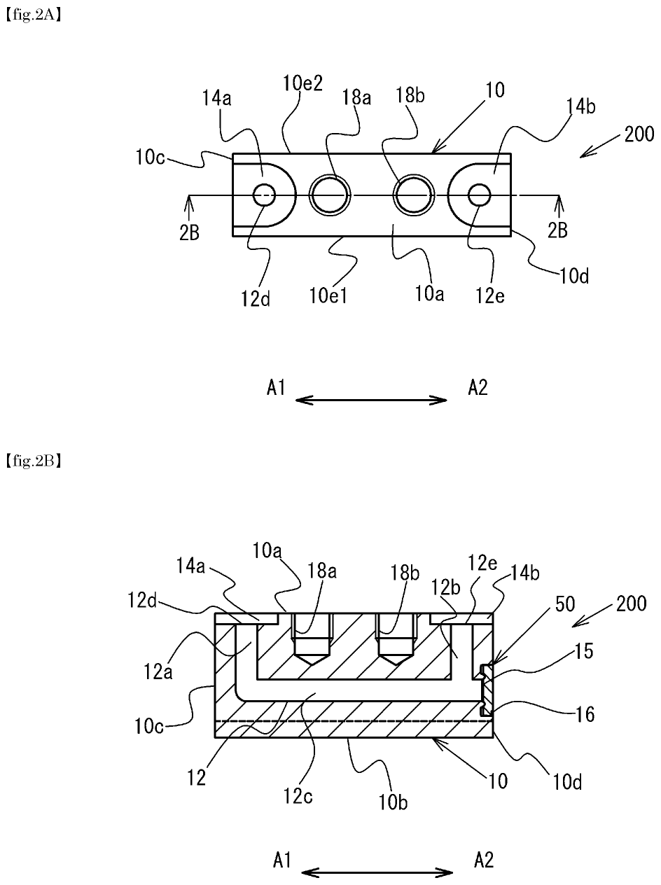

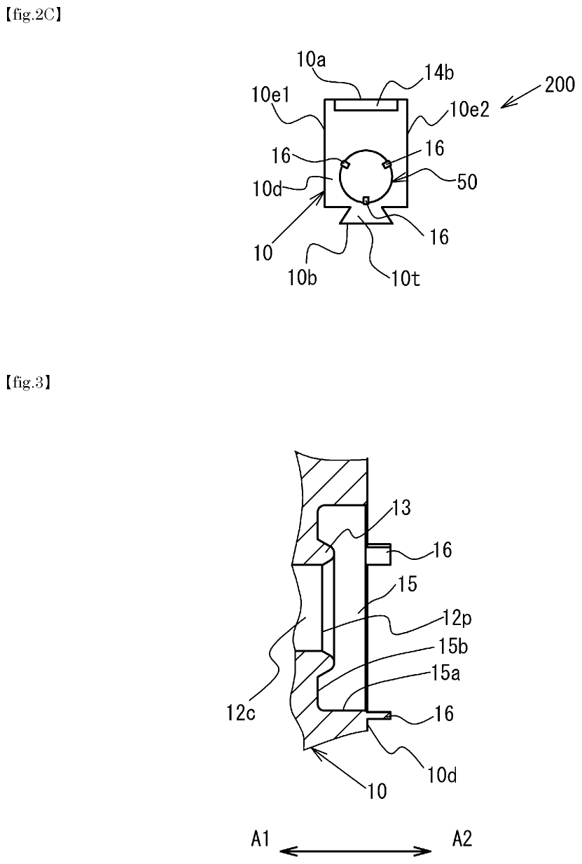

FIG. 2A to FIG. 2C illustrate an example of a structure of the joint block 200 described above.

The joint block 200 includes a block body 10 made of a metal such as a stainless alloy and a closing member 50 made of a metal such as a stainless alloy. It should be noted that, in the present embodiment, the metal constituting the block body 10 is a metal harder (for example, about 4 times) than the metal constituting the closing member 50. Further, in the following drawings, arrows A1, A2 indicate longitudinal directions of the block body 10, A1 being a side (hereinafter, referred to as one end side) on which the closing member 50 is not mounted, and A2 being a side (hereinafter, referred to as the other end side) on which the closing member 50 is mounted.

The block body 10 includes a top surface 10a and a bottom surface 10b, which are planes opposing each other, side surfaces 10e1, 10e2 each orthogonal to the top surface 10a, and end surfaces 10c, 10d orthogonal to these surfaces and disposed on both end portions in the longitudinal directions A1, A2. It should be noted that, while an example is given in which the block body 10 has a rectangular parallelepiped shape, another shape may be adopted.

An engaging part 10t formed so as to protrude to the bottom surface 10b side has a shape that fits together with a guide part (not illustrated) of the rail member 500, and is insertable from both end portions of the rail member 500 in the longitudinal directions G1, G2. Accordingly, the block body 10 is restrained on the rail member 500.

A flow path 12 defined by the block body 10 includes a first flow path 12c extending in the longitudinal directions A1, A2 and closed on the one end side A1 and opened on the other end side A2 in the longitudinal directions A1, A2, a second flow path 12a connected with the first flow path 12c on the one end side A1 in the longitudinal directions A1, A2 and communicating with a first opening 12d, and a third flow path 12b connected with the first flow path 12c on the other end side A2 in the longitudinal directions A1, A2 and communicating with a second opening 12e.

It should be noted that, while the second flow path 12a and the third flow path 12b are formed vertically to the top surface 10a and the first flow path 12c is formed parallelly with the top surface 10a, the arrangement is not necessarily limited thereto and the paths may be neither vertical nor horizontal.

The second flow path 12a and the third flow path 12b may be formed by machining, for example, by drilling a hole from the top surface 10a of the block body 10 in the vertical direction to form a blind hole. The first flow path 12c may be configured by drilling a hole with from the end surface 10d of the block body 10 in the vertical direction to form a blind hole. At this time, the first flow path 12c is formed at a height connected with tip end portions of the second flow path 12a and the third flow path 12b. When the hole for forming the first flow path 12c is opened from the end surface 10d of the block body 10, an opening of the first flow path 12c is formed on “the other end side” A2 of the block body 10. As described later, the opening of this first flow path 12c is closed by the closing member 50, and a U-shaped flow path configured by the second flow path 12a, the third flow path 12b, and the first flow path 12c is formed. It should be noted that a structure around the opening of the first flow path 12c is described later.

Holding recessed parts 14a, 14b for respectively holding gaskets are formed around the openings 12d, 12e that open on the top surface 10a side of the block body 10. A projection (not illustrated) having a circular shape and subjected to a hardening treatment to achieve a hardness sufficiently higher than that of the gasket in order to crush the gasket, may be formed on an outer periphery of each of the openings 12d, 12e on the bottom surfaces of the holding recessed parts 14a, 14b.

Two screw holes 18a, 18b that open at the top surface 10a and extend toward the bottom surface 10b side in the longitudinal directions A1, A2 are formed in the block body 10. The screw holes 18a, 18b are positioned between the two openings 12d, 12e that open at the top surface 10a. The screw holes 18a, 18b are, for example, size M5, include at least three threads, and have a depth of about 3 mm, but are not necessarily limited thereto. Dimensional specifications of the block body 10 are, for example, a width of about 10 mm, a length of about 30 mm, a diameter of the flow path 12 of about 2.6 mm, and a height of about 13 mm not including the engaging part 10t, but are not necessarily limited thereto. The screw holes 18a, 18b are used to couple the bodies of different fluid devices to the joint block 200. The widths of the block body 10 and the rail member 500 are approximately 10 mm, substantially matching.

FIG. 3 illustrates a main part enlarged sectional view of the other end side A2 of the block body 10 in the longitudinal directions A1, A2.

As illustrated in FIG. 3, a recessed part 15 is formed adjacent to an opening 12p of the first flow path 12c of the block body 10. The recessed part 15 defines a circumferential surface 15a formed concentrically with the opening 12p and an opposing surface 15b orthogonal to an axis of the first flow path 12c. In addition, a circular projection 13 constituting a seal mechanism described later is formed around the opening 12p. Furthermore, a plurality of protruding pieces 16 serving as swaging parts protruding to the other end side A2 in the longitudinal direction are integrally formed on the end surface 10d of the block body 10 adjacently to the inner peripheral surface 15a of the recessed part 15. As illustrated in FIG. 2C, the protruding pieces 16 are dispersed at equal intervals along the inner peripheral surface 15a.

FIG. 4 illustrates a structure of the closing member 50.

The closing member 50 is a metal member having a disk shape, and includes a projection 51 formed at a substantially central position of a peripheral surface 50a in a width direction, across a whole circumference thereof. The closing member 50 is formed with front-back symmetry, and either end surface 50e can also be used as an opposing surface opposing the opposing surface 15b of the block body 10 described above.

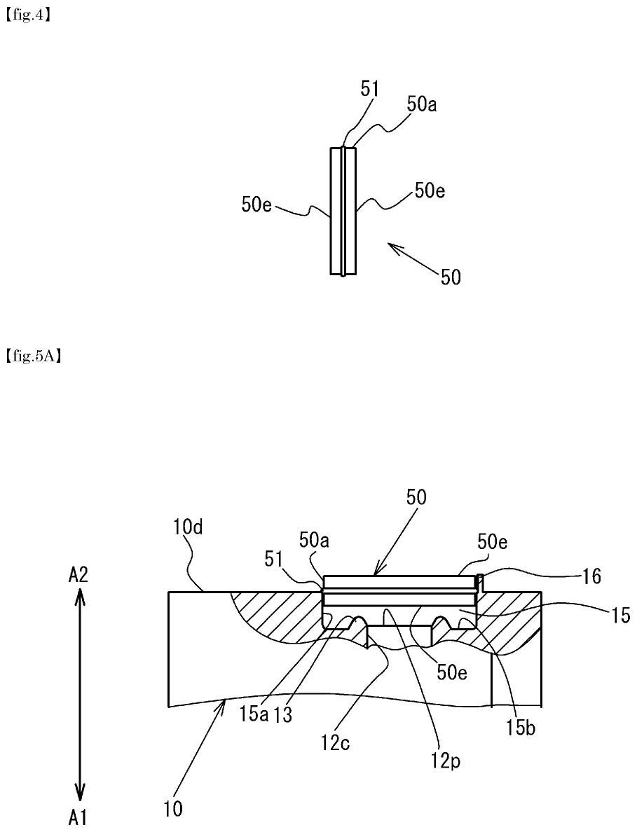

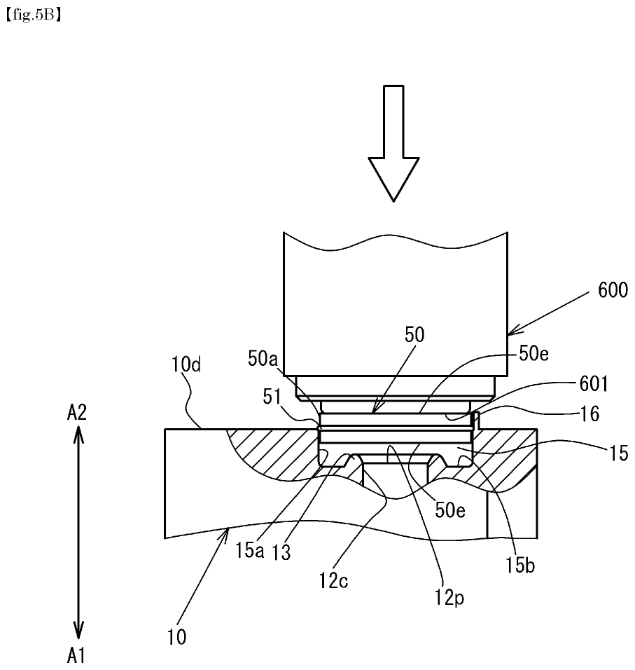

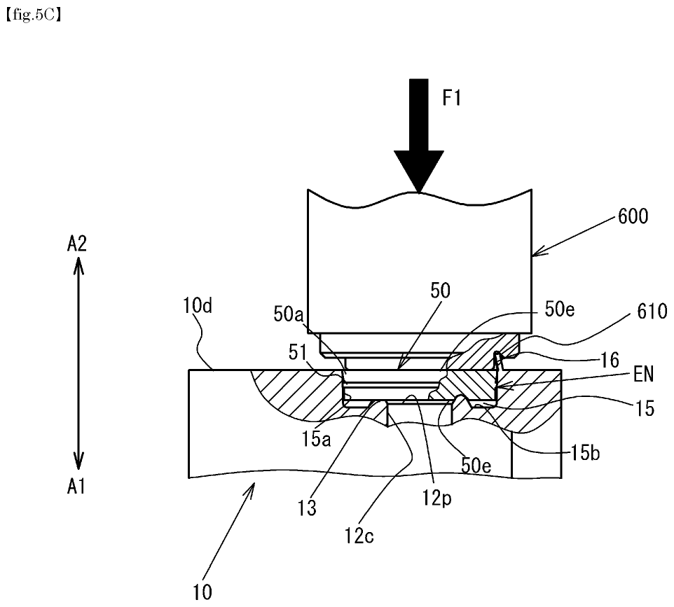

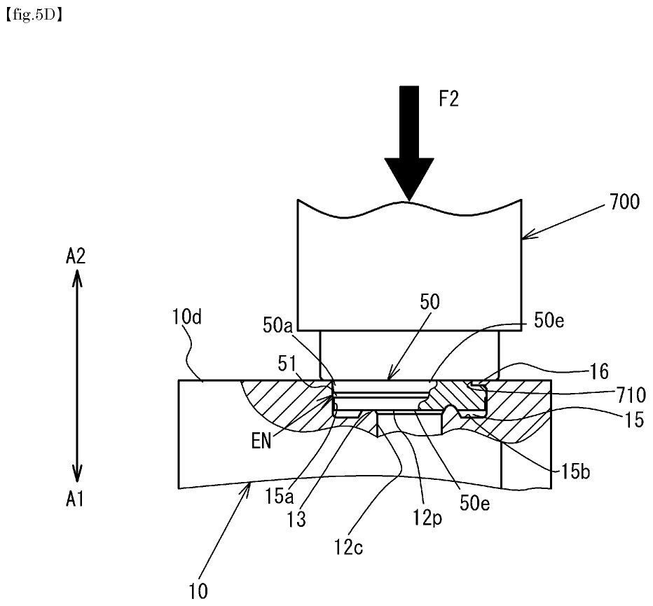

Next, assembly processes of a joint block 200 that uses the block body 10 and the closing member 50 having the above-described configuration will be described with reference to FIG. 5A to FIG. 5E.

First, as illustrated in FIG. 5A, the closing member 50 is positioned relative to the recessed part 15 of the block body 10. It should be noted that, during assembly, the block body 10 is fixed to a holder (not illustrated) so that the recessed part 15 faces upward.

As understood from FIG. 5A, an outer diameter of the peripheral surface 50a of the closing member 50 is formed slightly smaller than an inner diameter of the inner peripheral surface 15a of the recessed part 15, and an outer diameter of the projection 51 is formed slightly larger than the inner diameter of the inner peripheral surface 15a of the recessed part 15. Thus, while a portion of the closing member 50 on the one end side A1 from the projection 51 is fitted and inserted into the recessed part 15, the projection 51 interferes with the end surface 10d and the inner peripheral surface 15a and thus, the projection 51 does not enter the recessed part 15 only by the positioning.

Next, as illustrated in FIG. 5B, a jig 600 is lowered to bring a pressing surface 601 of the jig 600 into contact with the end surface 50e on an upper side of the closing member 50. At this time, the jig 600 is not in contact with the protruding pieces 16 formed on the block body 10.

Then, the closing member 50 is press-fitted into the recessed part 15 by the force of a load F1 in FIG. 5C. At this time, the projection 51 of the closing member 50 engages with the inner peripheral surface 15a of the recessed part 15, is crushed by the inner peripheral surface 15a, and plastically deformed. The load F1 is set to a magnitude necessary and sufficient for the projection 51 to be plastically deformed. Accordingly, an engaging part EN is formed.

As understood from FIG. 5C, the jig 600 includes an engaging recessed part 610 that engages with the protruding piece 16 and, in the forming process of the engaging part EN, the protruding piece 16 is also plastically deformed and inclined toward the recessed part 15 side.

Further, the end surface 50e on a lower side serving as the opposing surface of the closing member 50 is pressed toward the circular projection 13 formed around the opening 12p and, as illustrated in the drawing, a seal mechanism is configured in which the circular projection 13 bites into the end surface 50e on the lower side, sealing the area between the block body 10 and the closing member 50.

Then, as illustrated in FIG. 5D, when another jig 700 is lowered to further plastically deform the protruding piece 16 using a pressing surface 710 of the jig 700 with the force of a load F2, the protruding piece 16 is bent and housed in the recessed part 15, serving as the swaging part of the present invention.

As illustrated in FIG. 5E, the protruding piece 16 is housed in the recessed part 15, and the end surface 10d and the protruding piece 16 are disposed on a common plane.

As understood from the drawing, the pressing force that presses the end surface 50e serving as the opposing surface of the closing member 50 to the circular projection 13 is shared by the plurality of protruding pieces 16 deformed as swaging parts and the engaging part EN. That is, with the force that holds the sealing force of the seal mechanism shared by the swaging parts and the engaging part EN, the load F1 of the jig 600 and the load F2 of the jig 700 can be relatively reduced, making it possible to avoid application of an excessive load onto the block body 10.

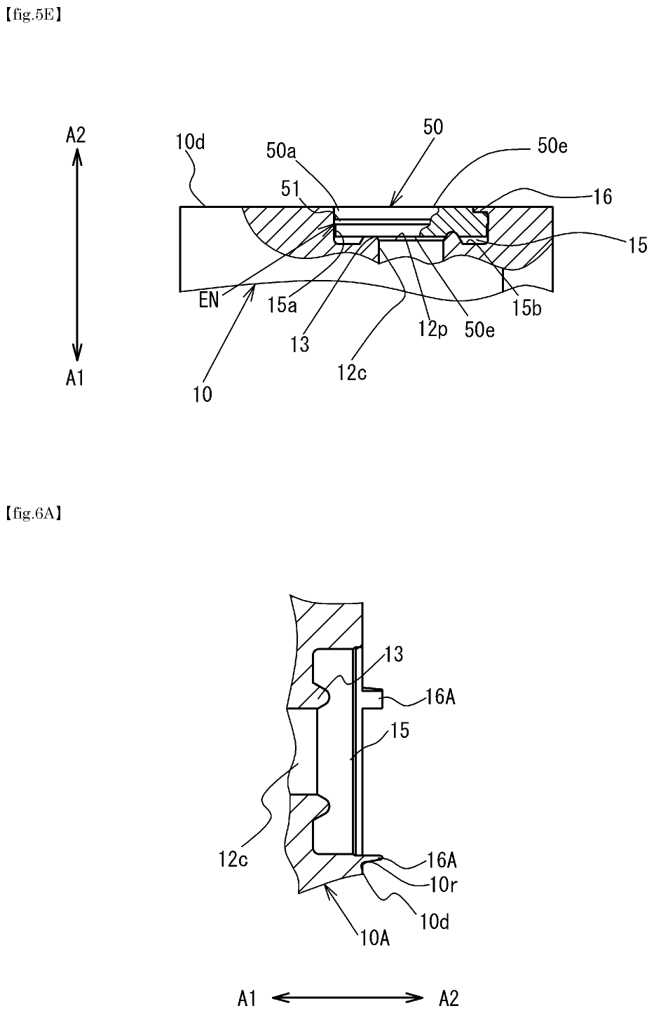

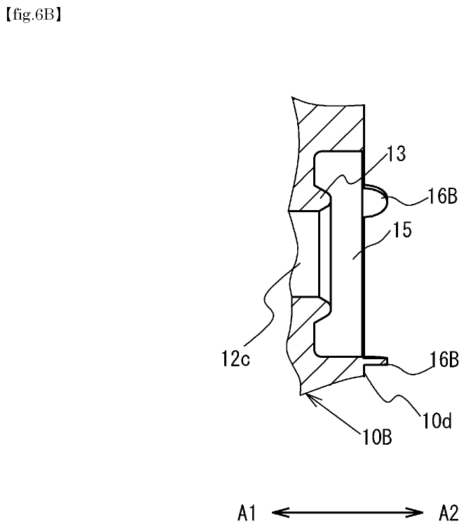

FIG. 6A to FIG. 6C illustrate modifications of the protruding piece formed on the block body 10. It should be noted that, in FIG. 6A to FIG. 6C, the same components as those in the above-described embodiment are denoted using the same reference numerals.

A protruding piece 16A illustrated in FIG. 6A is formed into a tapered shape having a thickness decreasing toward a tip end, and a groove 10r curved in a recessed shape is formed at a base of the protruding piece 16A on the end surface 10d. With such a configuration, the force that plastically deforms the protruding piece 16A can be reduced compared to that in the above-described embodiment.

A protruding piece 16B illustrated in FIG. 6B is formed so that a tip end portion is rounded. According to such a configuration, when the protruding piece 16B is bent, an edge of the protruding piece 16B is less likely to pierce the end surface 50e of the closing member 50, making it possible to avoid an extra load from being applied to the closing member 50.

A protruding piece 16C illustrated in FIG. 6C includes an enlarged area part having an enlarged area on the tip end portion. According to such a configuration, because the area that presses the end surface 50e of the closing member of the protruding piece 16C is enlarged, a sealing performance of the seal mechanism can be further stabilized.

### Second Embodiment

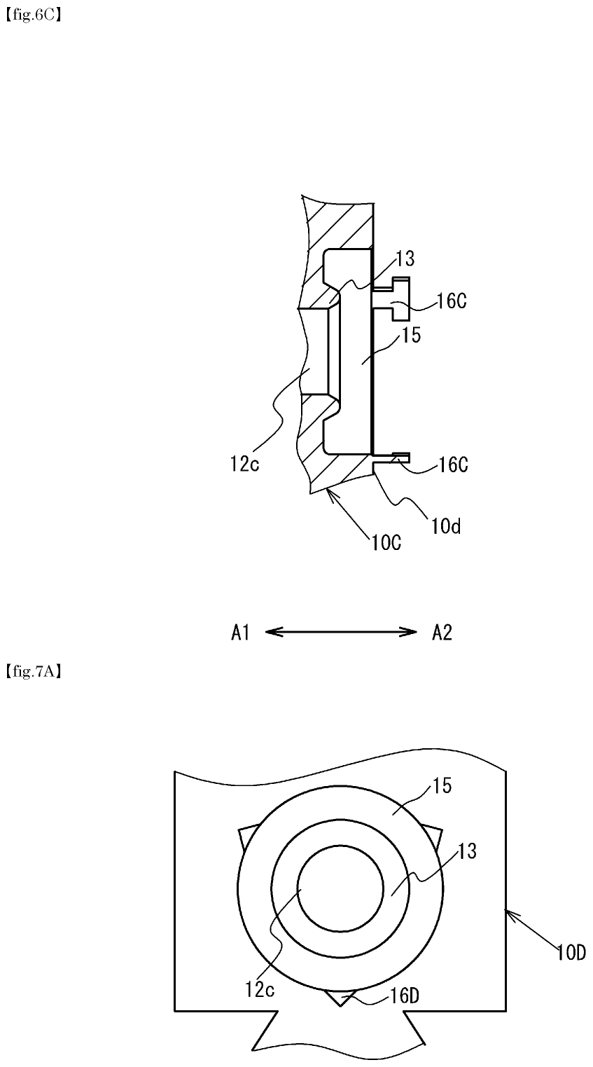

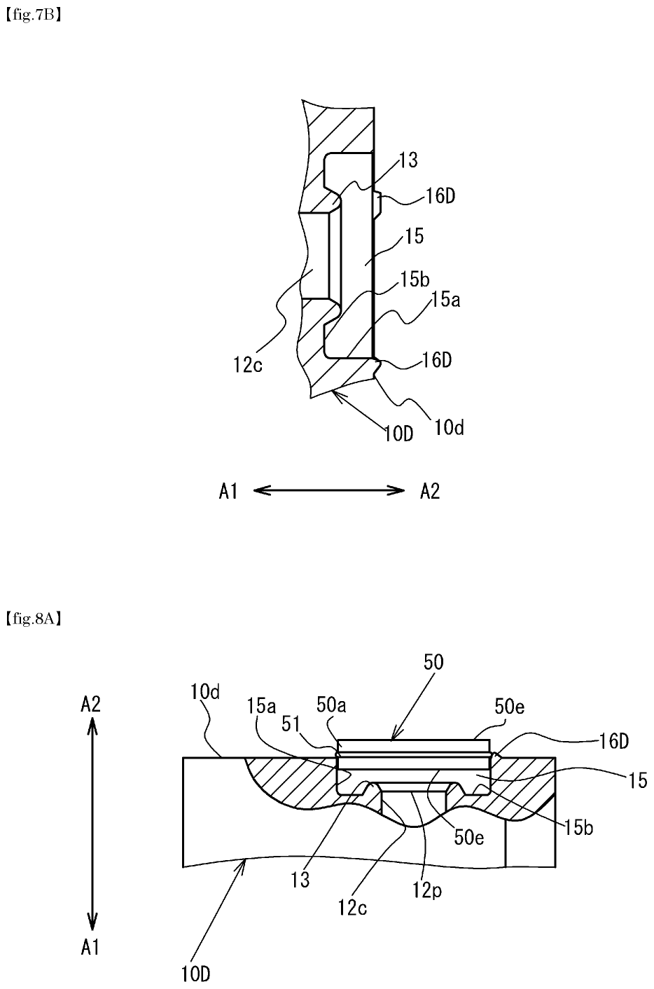

FIG. 7A and FIG. 7B illustrate the block body of the joint block according to a second embodiment of the present invention. It should be noted that, in FIG. 7A and FIG. 7B, the same components as those in the above-described embodiment are denoted using the same reference numerals.

A block body 10D includes, instead of the protruding parts 16 extending outwardly of the recessed part 15, a plurality of protruding parts 16D to be crushed by being pressed during swaging.

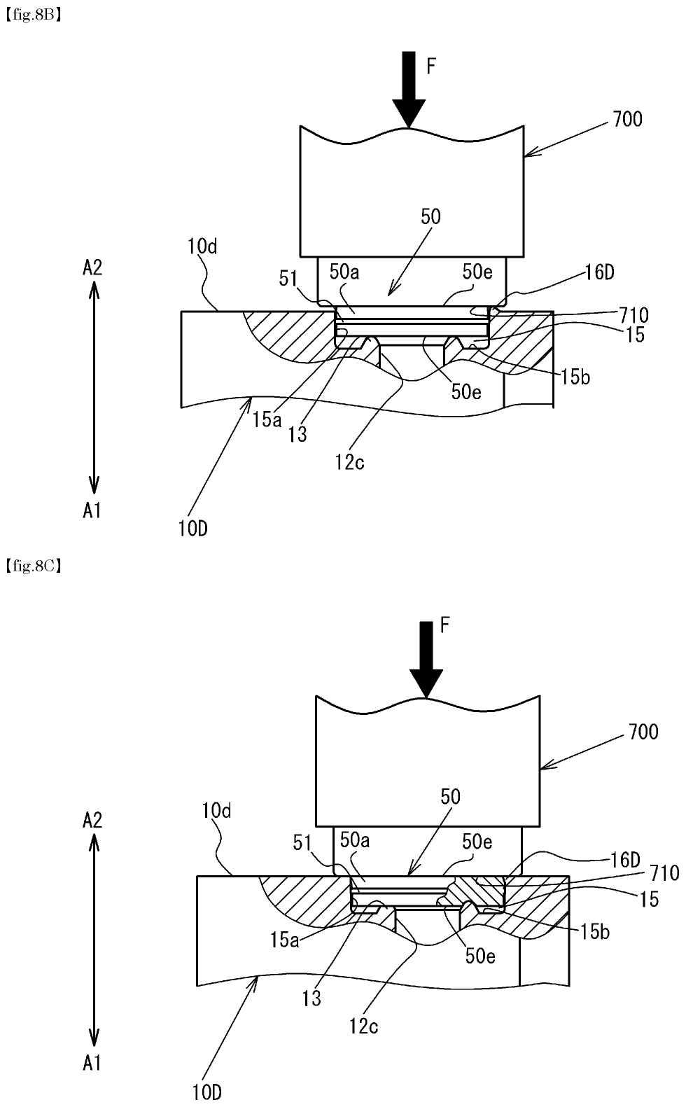

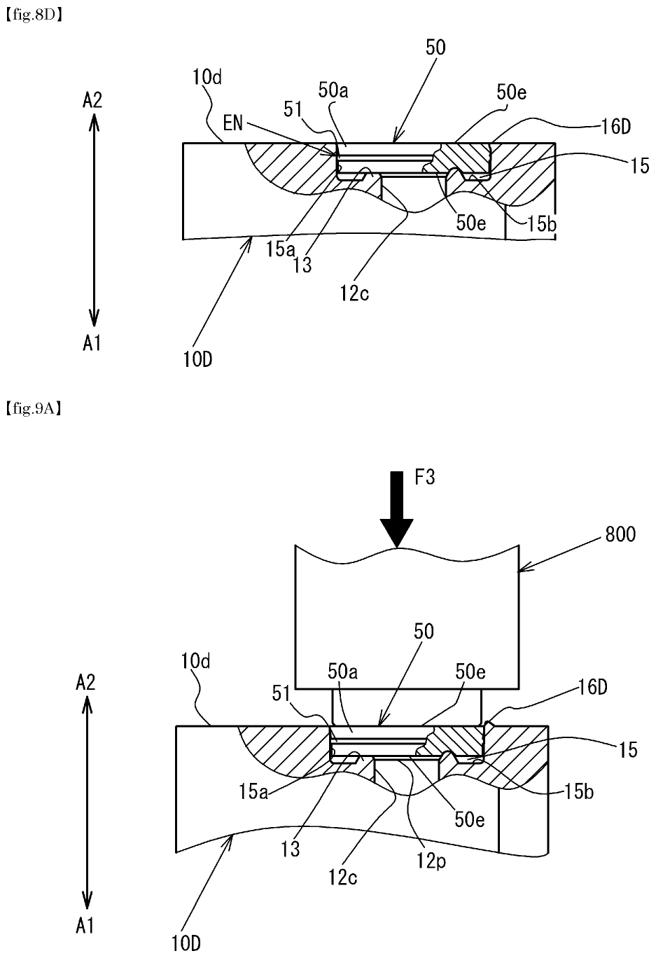

FIG. 8A to FIG. 8D illustrate assembly processes of the joint block that uses the block body 10D having the above-described configuration and the closing member 50 described above.

First, as illustrated in FIG. 8A, when the closing member 50 is positioned relative to the recessed part 15, the condition is the same as that described in FIG. 5A.

Then, when the closing member 50 is press-fitted into the recessed part 15 by the force of a load F while the pressing surface 710 of the jig 700 is brought into contact with the end surface 50e on the upper side of the closing member 50, the circular projection 13 bites into the end surface 50e on the lower side of the closing member 50 and the projection 51 of the closing member 50 is crushed and plastically deformed by the inner peripheral surface 15a of the recessed part 15.

When the jig 700 is further lowered, the plurality of protruding parts 16D of the block body 10D are also crushed, and the crushed protruding parts 16D is plastically deformed so as to fill an area between the inner peripheral surface 15a of the recessed part 15 and the peripheral surface 50a of the closing member 50 while deforming the peripheral surface 50a of the closing member 50. As a result, as illustrated in FIG. 8D, a seal mechanism in which the circular projection 13 bites into the end surface 50e on the lower side, sealing the area between the block body 10D and the closing member 50 is configured, and the swaging part 16 and the engaging part EN that share the force that holds the sealing force of the seal mechanism are configured.

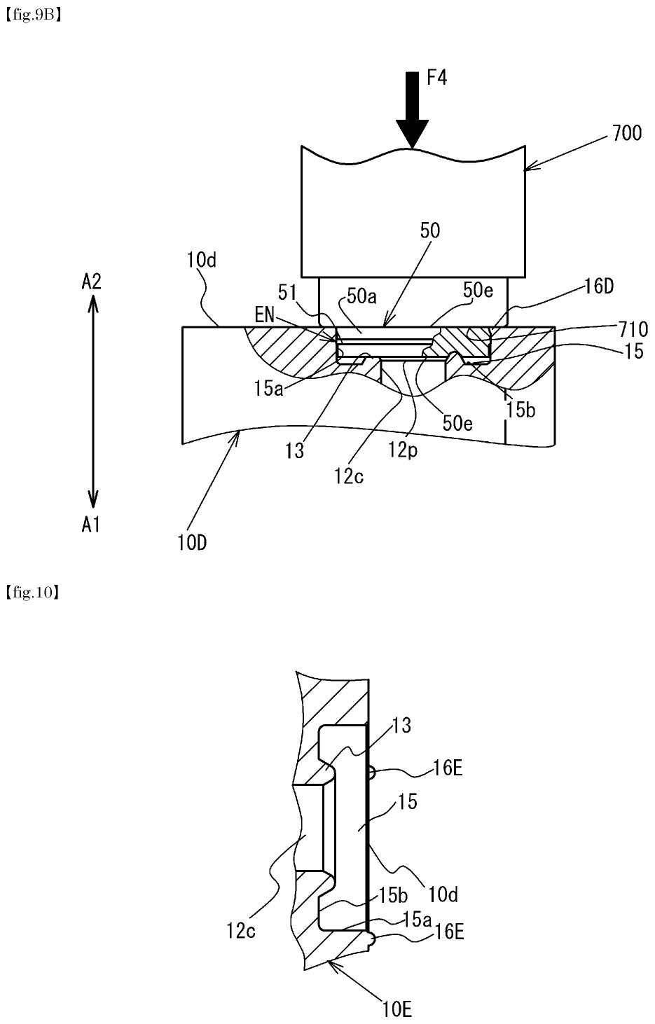

Next, FIG. 9A and FIG. 9B illustrate assembly processes different from those described in FIG. 8A to FIG. 8D.

In FIG. 8A to FIG. 8D, the common jig 700 is used to press-fit the closing member 50 and caulk the protruding part 16D in a common step.

As illustrated in FIG. 9A, first only the closing member 50 is press-fitted using a jig 800. Then, as illustrated in FIG. 9B, the protruding part 16D is caulked using the jig 700. Dividing the process in this way results in the advantage that loads F3, F4 can be separately set.

FIG. 10 illustrates a modification of the block body 10D illustrated in FIG. 7A and FIG. 7B. A plurality of projections 16E of a block body 10E are formed in a hemispherical shape. This makes it possible to optimize a shape of the projection 16E.

FIG. 11A and FIG. 11B illustrate another modification of the block body 10D. It should be noted that, in FIG. 11A and FIG. 11B, the same components as those in the above-described embodiment are denoted using the same reference numerals.

A block body 10F illustrated in FIG. 11A includes a groove 15c on the inner peripheral surface 15a of the recessed part 15. As the closing member, the same closing member 50 as that described in the first embodiment is used.

Assembly can be performed using the same assembling methods (two types of methods) as those in the second embodiment.

As illustrated in FIG. 11B, the engaging part EN is formed by the projection 51 of the closing member 50 being fit into the groove 15c of the recessed part 15.

### Third Embodiment

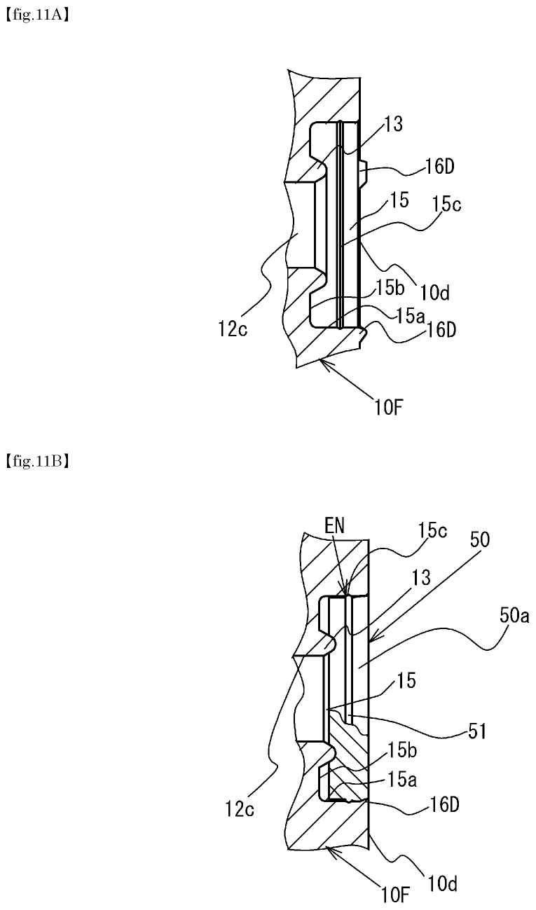

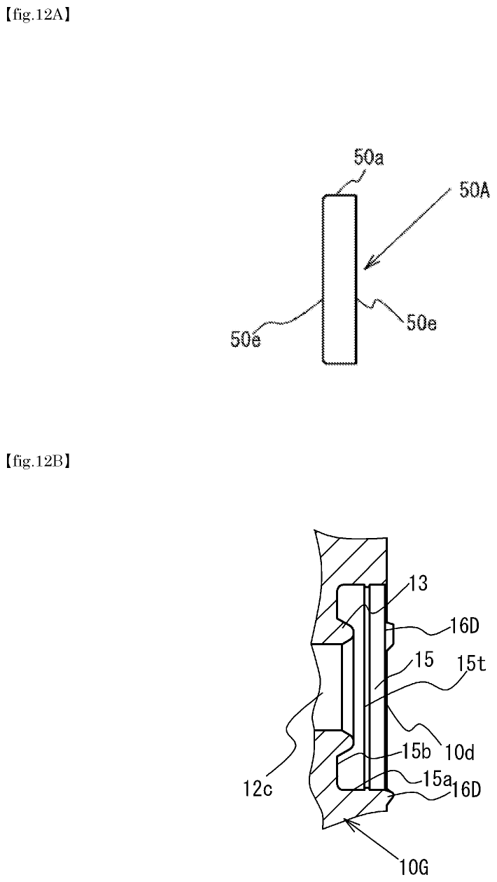

FIG. 12A to FIG. 12C illustrate the closing member, the block body, and the joint block according to a third embodiment of the present invention. It should be noted that, in FIG. 12A to FIG. 12C, the same components as those in the above-described embodiment are denoted using the same reference numerals.

A closing member 50A has a disk shape, and includes the peripheral surface 50a formed flat.

A block body 10G includes a projecting section 15t formed on the inner peripheral surface 15a of the recessed part 15.

When the same assembling methods (two types of methods) as those in the second embodiment are adopted, the closing member 50A is press-fitted into the recessed part 15, and the protruding part 16D is caulked, a seal mechanism is configured and the engaging part EN is formed by the projecting section 15t biting into the peripheral surface 50a of the closing member 50A, as illustrated in FIG. 12C. Further, the protruding part 16D constitutes a swaging part.

### Fourth Embodiment

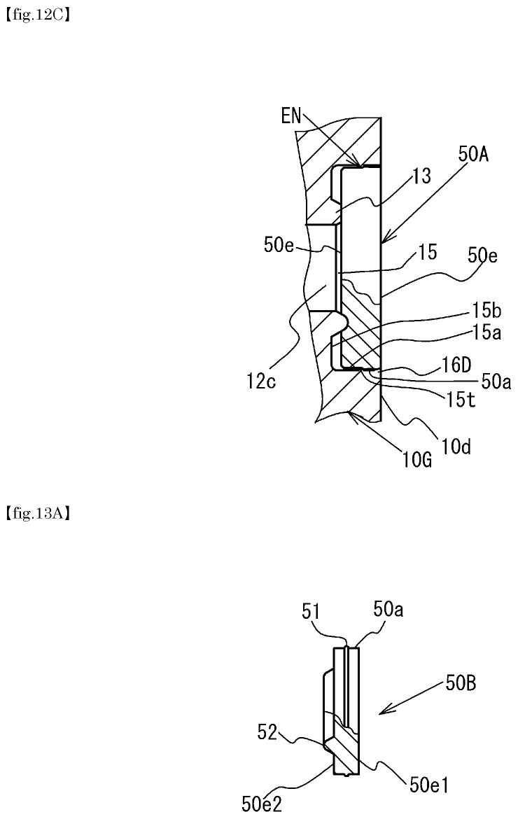

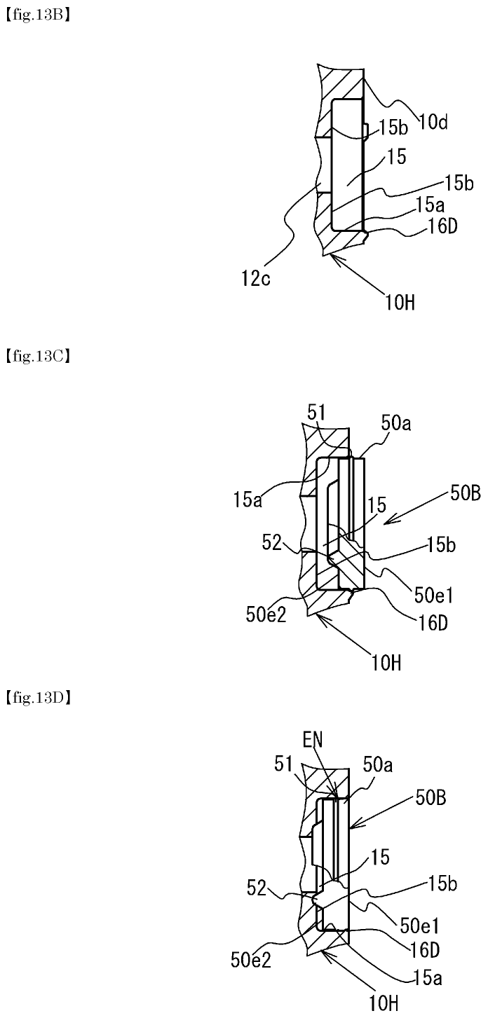

FIG. 13A to FIG. 13D illustrate a fourth embodiment of the present invention. It should be noted that, in FIG. 13A to FIG. 12D, the same components as those in the above-described embodiment are denoted using the same reference numerals.

In a closing member 50B illustrated in FIG. 13A, a circular projection 52 is formed on one end surface 50e2, and the other end surface 50e1 is a flat surface. The circular projection 52 is sufficiently harder than the other portion of the closing member 50B and is harder than the metal forming the block body due to a hardening treatment.

As illustrated in FIG. 13B, the opposing surface 15b of a block body 10H is a flat surface. As illustrated in FIG. 13C, when the closing member 50B is positioned relative to the recessed part 15, the projection 52 of the closing member 50B interferes with the end surface 10d. From this state, when the closing member 50B is press-fitted into the recessed part 15 and the protruding part 16D is caulked using the assembling method described above, the circular projection 52 bites into the opposing surface 15b to constitute a seal mechanism, the projection 51 is crushed to constitute the engaging part EN, and the protruding part 16D constitutes the swaging part, as illustrated in FIG. 13D.

### Fifth Embodiment

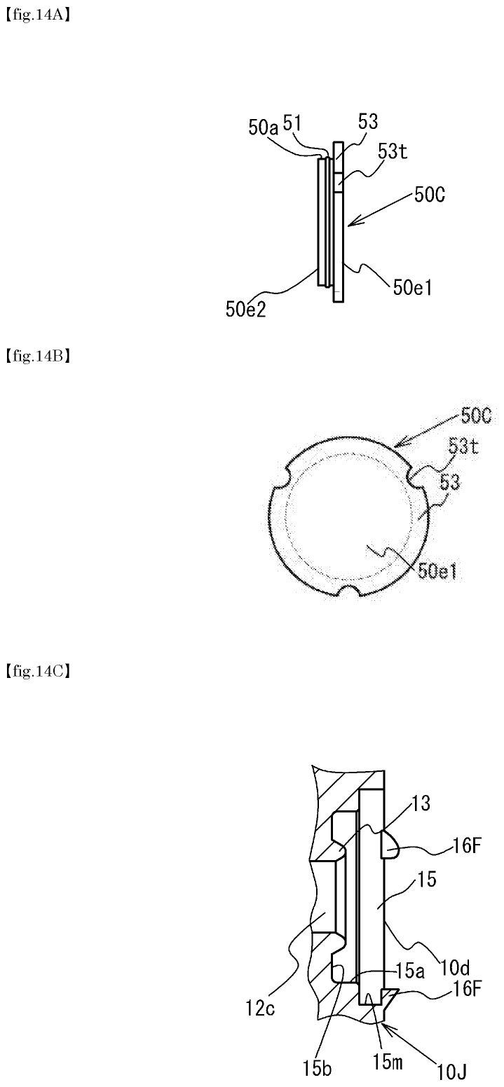

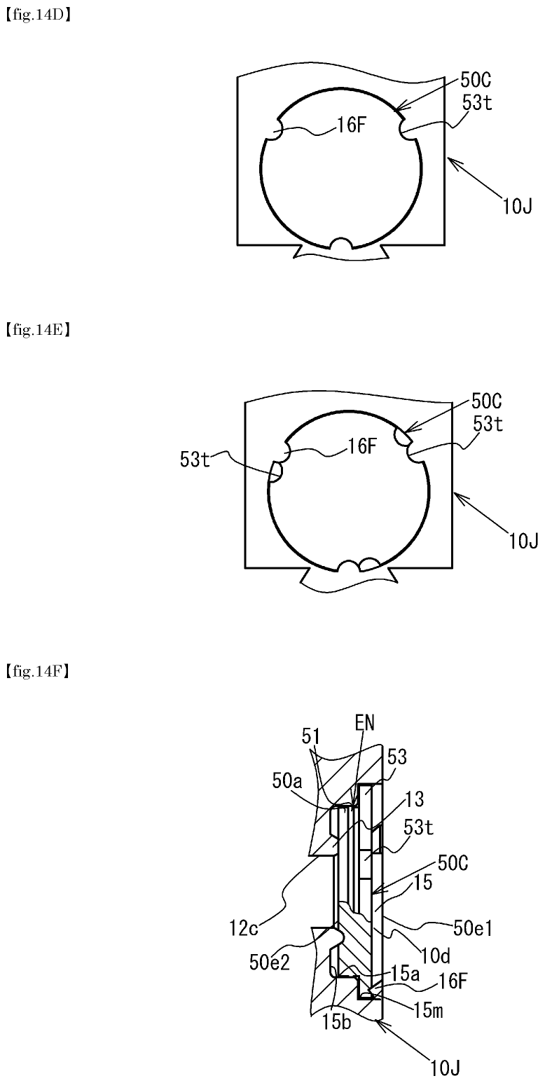

FIG. 14A to FIG. 14F illustrate a fifth embodiment of the present invention. It should be noted that, in FIG. 14A to FIG. 14F, the same components as those in the above-described embodiment are denoted using the same reference numerals.

A closing member 50C illustrated in FIG. 14A and FIG. 14B includes an expanded diameter part 53 having an outer diameter larger than those of the peripheral surface 50a and the projection 51 on the other end surface 50e1 on a side opposite to the one end surface 50e2. A recessed part 53t is formed at equal intervals in the circumferential direction at the outer peripheral edge part of the expanded diameter part 53.

In a block body 10J illustrated in FIG. 14C, an enlarged recessed part 15m capable of housing the expanded diameter part 53 described above is formed on the end surface 10d side of the recessed part 15. Further, a plurality of projections 16F are formed at positions corresponding to the recessed part 53t.

As illustrated in FIG. 14D, when the recessed parts 53t of the closing member 50C are aligned with the projections 16F of the block body 10J and the closing member 50 is inserted, the recessed parts 53t respectively pass through the projections 16F, thereby the closing member 50C is housed in the recessed part 15.

Then, as illustrated in FIG. 14E, the closing member 50C is rotated in one direction to shift the positions of the recessed parts 53t from the projections 16F.

Subsequently, the projections 16F are caulked, thereby forming the seal mechanism, the engaging part EN, and the swaging part 16F, as illustrated in FIG. 14F.

### Sixth Embodiment

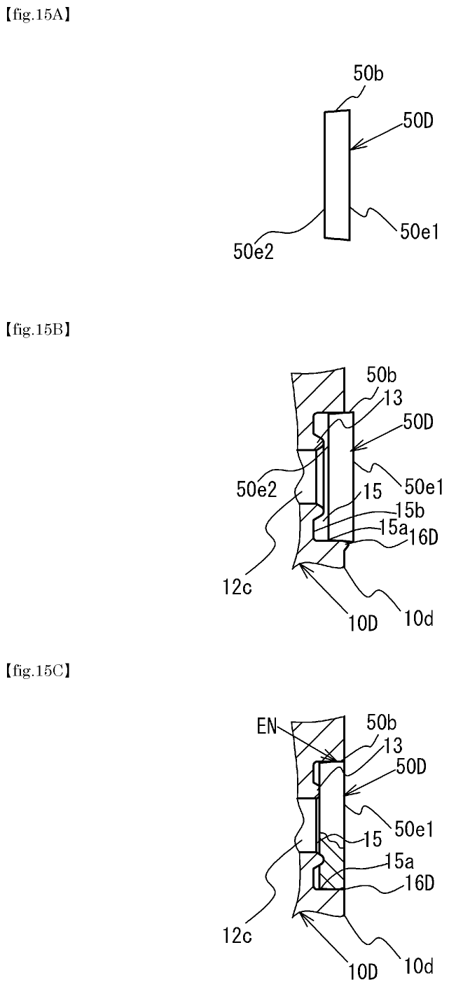

FIG. 15A to FIG. 15C illustrate a sixth embodiment of the present invention. It should be noted that, in FIG. 15A to FIG. 15C, the same components as those in the above-described embodiment are denoted using the same reference numerals.

A closing member 50D illustrated in FIG. 15A has a disk shape, but includes a tapered peripheral surface 50b.

As illustrated in FIG. 15B, when the closing member 50D is positioned in the recessed part 15 of the block body 10D, only a portion of the tapered peripheral surface 50b on a small diameter side enters the recessed part 15 and interference occurs in the middle.

As illustrated in FIG. 15C, when the closing member 50D is press-fitted into the recessed part 15 of the block body 10D, a large diameter side of the tapered peripheral surface 50b is plastically deformed, and the engaging part EN is formed. When the protruding part 16D is caulked, a swaging part is formed.

FIG. 16A and FIG. 16B illustrate a modification of the closing member.

A closing member 50E includes a plurality of projecting sections 50c extending in the circumferential direction and arranged at equal intervals on the peripheral surface 50a.

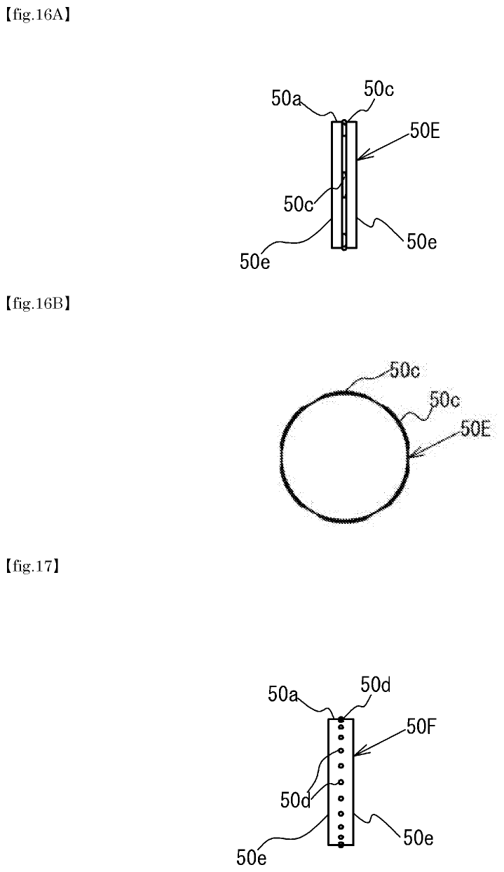

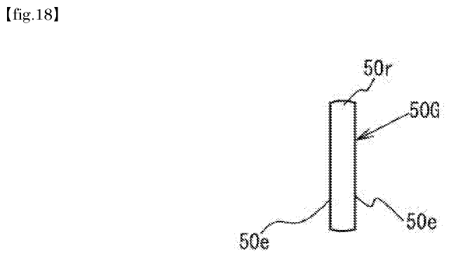

As illustrated in FIG. 17, hemispherical projections 50d can also be formed at equal intervals in the circumferential direction on the peripheral surface 50a of a closing member 50F.

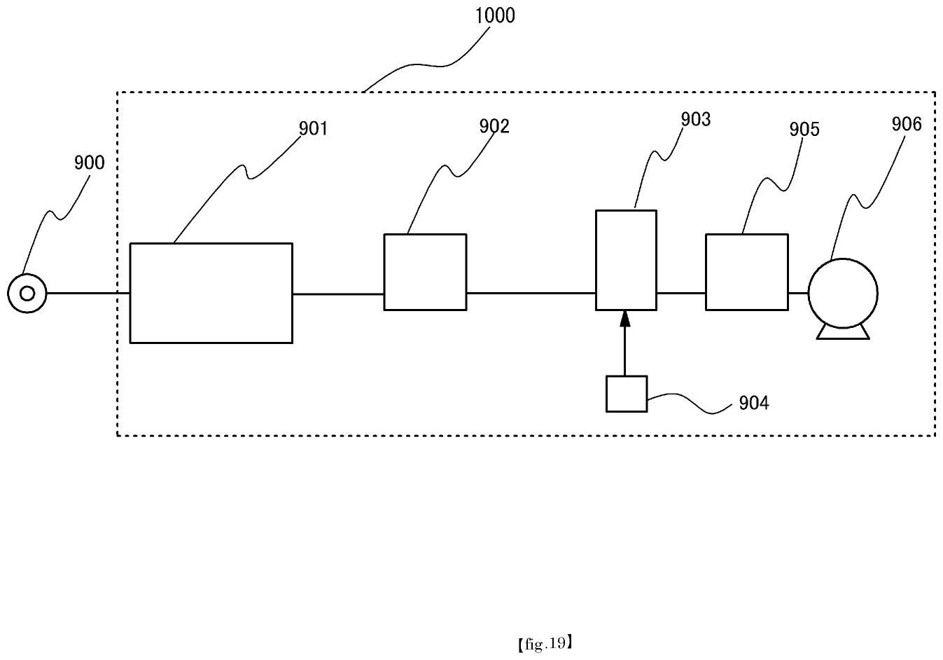

As illustrated in FIG. 18, a closing member 50G including a peripheral surface 50r convexly curved can also be adopted.

Next, application examples of the fluid control system illustrated in FIG. 1 will be described with reference to FIG. 19.

A semiconductor manufacturing system 1000 illustrated in FIG. 19 is a system for executing a semiconductor manufacturing process by an atomic layer deposition (ALD) method, with 900 denoting a process gas supply source, 901 denoting a gas box (fluid control system), 902 denoting a tank, 903 denoting a switch valve, 904 denoting a control unit, 905 denoting a processing chamber, and 906 denoting an exhaust pump.

In the semiconductor manufacturing process based on the ALD method, the flow rate of the process gas needs to be precisely adjusted and a certain amount of flow rate needs to be secured to address an increase in the size of a diameter of the substrate.

The gas box 901 incorporates the fluid control system described above in which various fluid devices, such as a switch valve, a regulator, and a mass flow controller, are integrated and housed in a box to supply an accurately measured process gas to the processing chamber 905.

The tank 902 functions as a buffer for temporarily storing the process gas supplied from the gas box 901.

The switch valve 903 controls the flow rate of the gas measured in the gas box 901.

The control unit 904 controls the switch valve 903 to execute flow control.

The processing chamber 905 provides a sealed treatment space for forming a film on the substrate by the ALD method.

The exhaust pump 906 draws a vacuum inside the processing chamber 903.

While a case in which the fluid control system is used in a semiconductor manufacturing process based on the ALD method is illustrated in the above-described application example, the present invention is not necessarily limited thereto, and can be applied to various targets that require precise flow adjustment, such as an atomic layer etching (ALE) method, for example.

### DESCRIPTIONS OF REFERENCE NUMERALS

| | |
|---|---|
| 10 to 10J | Block body |
| 10a | Top surface |
| 10b | Bottom surface |
| 10c | End surface |
| 10d | End surface |
| 10e1 | Side surface |
| 10e2 | Side surface |
| 10r | Groove |
| 10t | Engaging part |
| 12 | Flow path |
| 12a | Second flow path |
| 12b | Third flow path |
| 12c | First flow path |
| 12d | First opening |
| 12e | Second opening |
| 12p | Opening |
| 13 | Circular projection |
| 14a | Holding recessed part |
| 14b | Holding recessed part |
| 15 | Recessed part |
| 15a | Inner peripheral surface |
| 15b | Opposing surface |
| 15c | Groove |
| 15m | Enlarged recessed part |
| 15t | Projecting section |
| 16, 16A to 16C | Protruding piece (Swaging part) |
| 16D | Protruding part (Swaging part) |
| 16E | Projection |
| 16F | Projection |
| 18a | Screw hole |
| 18b | Screw hole |
| 50 to 50G | Closing member |
| 50a | Peripheral surface |
| 50b | Peripheral surface |
| 50c | Projecting section |
| 50d | Projection |
| 50e | End surface |
| 50e1 | Other end surface |
| 50e2 | One end surface |
| 50r | Peripheral surface |
| 51 | Projection |
| 52 | Projection |
| 53 | Expanded diameter part |
| 53t | Recessed part |
| 110A to 110E | Fluid device |
| 200 | Joint block |
| 310 | Introducing pipe |
| 500 | Rail member |
| 600 | Jig |
| 601 | Pressing surface |
| 610 | Engaging recessed part |
| 700 | Jig |
| 710 | Pressing surface |
| 800 | Jig |
| 900 | Process gas supply source |
| 901 | Gas box (Fluid control system) |
| 902 | Tank |
| 903 | Switch valve |
| 904 | Control unit |
| 905 | Processing chamber |
| 906 | Exhaust pump |
| 1000 | Semiconductor manufacturing system |
| A1, A2 | Longitudinal direction |
| BS | Base plate |
| EN | Engaging part |
| G1, G2 | Longitudinal direction |
| W1, W2 | Width direction |

1. A joint block provided with a first opening, a second opening, and a flow path connecting the first opening and the second opening, comprising:
a block body that defines a first flow path extending in a longitudinal direction and closed on one end side and opened on the other end side in the longitudinal direction, a second flow path connected with the first flow path on one end side in the longitudinal direction and communicating with the first opening, and a third flow path connected with the first flow path on the other end side in the longitudinal direction and communicating with the second opening;
a closing member mounted in a recessed part formed on the other end side of the block body in the longitudinal direction;
a seal mechanism that includes an annular projection formed on one of opposing surfaces of the block body and the closing member opposing one another, and seals an area between the block body and the closing member by the annular projection biting into the other opposing surfaces around an opening of the first flow path;
a swaging part that is formed on the block body and presses the closing member toward the opposing surface of the block body; and
an engaging part formed by an inner peripheral part of the recessed part and an outer peripheral part of the closing member that engages with the inner peripheral part,
wherein a pressing force that presses the annular projection of the seal mechanism against the other opposing surface is shared by the swaging part and the engaging part.

2. The joint block according to claim 1, wherein
the engaging part is formed by an inner peripheral surface of the recessed part and an outer peripheral part of the closing member elastically deformed by being press-fitted into the inner peripheral surface.

3. The joint block according to claim 1, wherein
the engaging part includes a projection formed on the inner peripheral surface of the recessed part or the outer peripheral surface of the closing member, and a groove formed on the inner peripheral surface of the recessed part or the outer peripheral surface of the closing member and fitted with the projection.

4. The joint block according to claim 1, wherein
the swaging part is dispersed around the closing member.

5. The joint block according to claim 1, wherein
the swaging part is formed so as to be housed in the recessed part.

6. The joint block according to claim 4, wherein
the swaging part is formed so as to press a back surface of the closing member on a side opposite to the opposing surface toward the opposing surface of the block body.

7. The joint block according to claim 4, wherein
the swaging part is formed to fill an area between the inner peripheral surface of the recessed part and the outer peripheral surface of the closing member.

8. A manufacturing method of a joint block provided with a first opening, a second opening, and a flow path connecting the first opening and the second opening, comprising:
preparing a block body that defines a first flow path extending in a longitudinal direction and closed on one end side and opened on the other end side in the longitudinal direction, a second flow path connected with the first flow path on one end side in the longitudinal direction and communicating with the first opening, and a third flow path connected with the first flow path on the other end side in the longitudinal direction and communicating with the second opening, and a closing member;
positioning the closing member in a recessed part formed on the other end side of the block body in the longitudinal direction;
press-fitting the closing member into the recessed part to form an engaging part that engages an inner peripheral part of the recessed part and an outer peripheral part of the closing member;
deforming a swaging part formed on the block body to press the closing member toward an opposing surface of the block body; and
causing an annular projection formed on one of opposing surfaces of the block body and the closing member opposing one another to bite into the other opposing surfaces around an opening of the first flow path to seal an area therebetween.

9. The manufacturing method of a joint block according to claim 8, comprising:
forming the engaging part; and
deforming the swaging part,
the forming and the deforming being executed in a common stage.

10. A fluid control system comprising a flow path between fluid devices connected using the joint block described in claim 1.

11-13. (canceled)
